(19) United States
(12) Patent Application Publication
(10) Pub. No.: US 2021/0075191 A1
(43) Pub. Date: Mar. 11, 2021

(54) Laser system for Generating Single-Sideband Modulated Laser Radiation

(71) Applicant: TOPTICA Projects GmbH, Graefelfing (DE)

(72) Inventors: Martin Enderlein, Munich (DE); Armin Zach, Windach (DE)

(73) Assignee: TOPTICA Projects GmbH, Graefelfing (DE)

(21) Appl. No.: 16/565,778

(22) Filed: Sep. 10, 2019

(51) Int. Cl. H01S 5/0683; H01S 5/024; H01S 5/042

(52) U.S. Cl. CPC H01S 5/06835; G02B 5/18; H01S 5/0424; H01S 5/02407

(57) ABSTRACT

The invention relates to a laser system comprising a laser light source (1) that emits laser radiation during operation of the laser system, a modulation means (2) that brings about modulation of the laser radiation emitted by the laser light source (1) such that the spectrum of the laser radiation comprises a carrier (14) and two sidebands (13, 15) that are symmetrically distributed around the carrier, and at least one optical amplifier (5) that amplifies the radiation emitted by the laser light source (1). The invention proposes that an optical filter (4) be provided in the beam path of the laser radiation, upstream of the optical amplifier (5), which filter is intended for removing the spectral portion of the laser radiation at the frequency of one of the two sidebands (13). The laser system is suitable inter alia for generating an artificial guide star (“laser guide star”) for astronomical telescopes comprising adaptive optics. The invention furthermore relates to a method for generating single-sideband modulated laser radiation.

### FIELD OF THE INVENTION

The invention relates to a laser system comprising
a laser light source that is configured to emit laser radiation during operation of the laser system,
a modulation means that is configured for modulating the emitted laser radiation such that the frequency spectrum of the laser radiation comprises a carrier and two sidebands that are symmetrically distributed around the carrier, and
at least one optical amplifier that is configured for amplifying the laser radiation.

The invention furthermore relates to a method for generating laser radiation, comprising the method steps of
generating laser radiation by means of a laser light source;
modulating the laser radiation such that the spectrum of the laser radiation comprises a carrier and two sidebands that are symmetrically distributed around the carrier, and
amplifying the laser radiation.

### BACKGROUND OF THE INVENTION

Known laser systems use sideband modulated laser radiation that is amplified and frequency-doubled. This can be used for example for exciting sodium atoms in the mesosphere, in a resonant manner, to fluorescence. In this manner, a punctiform artificial star results, which can be used as a reference for astronomical telescopes comprising adaptive optics. The demands on suitable laser systems for generating artificial guide stars of this kind are high. Ideally, a high power of 20 W or more is required, specifically at a line width of from a few GHz to less than 5 MHz at the sodium resonance of 589 nm (sodium D-line). In order to achieve an adequate intensity of the artificial guide star, as intensive as possible an interaction between the laser and the few sodium atoms in the mesosphere must be achieved. In this case, it should be ensured that the electronic excitation pattern of the sodium atom is not simply a 2-level system. In particular the hyperfine structure of the excited fluorescence line is of importance. The hyperfine splitting makes it possible for the fluorescence electron to be optically pumped into a non-resonant state following a few excitation cycles, i.e. a state from which there is no resonant optical transition at the laser frequency (fluorescence frequency). Thereafter, the electron is no longer available for fluorescence, resulting in an immediate loss of the associated atoms for the fluorescence backscattering. This can be countered by means of a second spectral component being added to the laser light, specifically one at what is referred to as the “back-pumping frequency”, in addition to that at the fluorescence frequency. The fluorescence frequency excites fluorescence at the corresponding sodium resonance. The back-pumping frequency is detuned, relative to the fluorescence frequency, by the amount corresponding to the hyperfine splitting of the relevant sodium line, and causes the excitation electron to be “pumped back” out of the non-resonant state and to thus be available again for the fluorescence process. In this way, the intensity of the fluorescence light can be significantly increased. The back-pumping frequency can be generated for example by means of modulation (sideband modulation) of the laser. In this case, the laser spectrum consists of a carrier at the fluorescence frequency and at least one sideband at a back-pumping frequency.

In known laser systems, a semiconductor laser is used as the laser light source, wherein the back-pumping sideband is generated by means of sine modulation of the injection current of the laser diode. Alternatively, the modulation of the laser radiation may be achieved using an electro-optic modulator arranged in the beam path, downstream of the laser light source. The sine modulation always results in sidebands that are arranged symmetrically around the carrier, i.e. having a lower and higher frequency than the carrier. For application purposes, however, only one of the sidebands is generally required; at best, the second sideband at least does not interfere with the application.

In the case of laser systems of this kind, it may be disadvantageous that the portion of the optical power in the unused sideband does not contribute to increasing the fluorescence, and therefore reduces the efficiency of the laser when generating fluorescence light. There is correspondingly less power available in the sideband that is actually used. Moreover, in many applications it is possible that the unused second sideband may generate additional scattered light (Rayleigh scattering) and thus reduce the signal/noise ratio.

In the context of the laser-generated artificial guide star, without a superfluous second sideband a spectrum of the laser radiation used may have further significant advantages: In order to increase the coupling of the laser radiation to the atomic transition, frequency modulation of the laser (“chirping”) is often used, during which the interaction of the laser with various speed classes of the atomic assembly is controlled. Any unnecessary frequency component in the laser spectrum can reduce the efficiency of this method. Furthermore, the narrow-band laser can generate Raman signals both at the frequency of the carrier and at the frequencies of the sidebands (see also e.g. Vogt et al., “Detection and Implications of Laser-Induced Raman Scattering at Astronomical Observatories”, Phys. Rev. X, 2017), which can interfere with the instruments used. Single-sideband modulated laser radiation makes it possible to reduce the number of Raman lines by up to one third.

In the applications of interest, the frequency spacing between the carrier and the sideband is in the high MHz to GHz range (e.g. 1.7 GHz in the case of the sodium hyperfine structure). Direct generation of single-sideband modulated laser radiation, e.g. by means of serrodyne (sawtooth) modulation, can hardly be implemented in practice owing to the high Fourier components involved. Single-sideband modulation using a plurality of or more complex electro-optic modulators (e.g. dual-drive Mach-Zehnder modulator) is laborious and expensive in practice. In particular, modulators of this kind are not commercially available at the specific laser wavelengths necessary for the excitation of the various atomic species.

Sideband modulated (e.g. single-sideband modulated) laser radiation is also of interest for other applications, in addition to the generation of artificial guide stars in astronomy. In many applications in atomic physics, quantum technology, including quantum information technology and spectroscopy, it is essential to maximize the time period of the interaction of a laser beam with an atom or a set of atoms. These applications include, inter alia, laser cooling of atoms, as well as, very generally, the generation of fluorescence signals, e.g. in spectroscopy. In this case, in order to maximize the interaction time, two-level systems are frequently used, which systems allow for cyclical excitation. Examples for this are, in general, alkali atoms or earth alkali ions, in the case of which the hyperfine structure in the ground state should again be taken into account. In order to increase the efficiency in the case of laser cooling or the generation of resonance fluorescence of said alkali atoms or earth alkali ions, it is therefore helpful and conventional, in this case too, to additionally provide a second laser frequency (typically in the form of a complete second laser system), as well as the carrier that drives the quasi cyclical transition in the atom, wherein the frequency spacing of the two component corresponds to the hyperfine structure of the atomic ground state, in order to return the atoms to the ground state of the quasi cyclical transition, by means of optical pumping, such that said atoms can contribute to the fluorescence.

### SUMMARY OF THE INVENTION

There is a need for a laser system and a method that generate single-sideband modulated laser radiation in a practical manner, and specifically having a frequency spacing between the carrier and sideband that is in the (high) MHz- to GHz-range.

For this purpose, it is proposed that an optical filter should be arranged in the beam path of the laser radiation, upstream of the optical amplifier, which filter is configured to remove the spectral portion of the laser radiation at the frequency of one of the two sidebands.

Furthermore, in the case of a method of the type specified at the outset, it is proposed that the modulated laser radiation should pass through an optical filter prior to amplification, which filter removes the spectral portion of the laser radiation at the frequency of one of the two sidebands.

The invention combines (sine) modulation of the laser radiation, by means of which two sidebands symmetrically distributed around the carrier are initially generated, with an optical filter that removes the undesired sideband.

Within the meaning of the invention, the undesired sideband is sufficiently removed from the spectrum when it is weakened by at least 13 dB, preferably at least 20 dB, relative to the other (desired) sideband.

The filter is preferably an optical notch filter. Said filter is characterized in that it makes it possible to filter out optical frequencies within a narrow frequency range. The filter visibly adds a notch into the spectrum of the laser radiation. The notch in the filter spectrum coincides with the frequency of the sideband that is to be removed.

The optical filter should be sufficiently narrow-band and have a high degree of edge steepness, in order to be able to separate the sideband from the carrier. Furthermore, the filter bandwidth should also be sufficiently large, specifically larger than the laser bandwidth (typically <10 MHz), in order that the undesired sideband can be completely removed. In other words, the filter bandwidth should be narrow compared with the spacing between the carrier and sideband, i.e. narrower than the modulation frequency (in practical cases, in the range of from 800 MHz to 13 GHz; 1.7 GHz in the case of sodium).

In the case of a laser system for generating an artificial guide star, it is necessary to take into account the possibility of quick frequency detuning of the laser radiation source, for the purpose of what is known as frequency chirping. In order to increase the coupling efficiency of the laser beam at the atomic transition, frequency chirping of the laser radiation (typically sawtooth-shaped) having amplitudes of up to 500 MHz and periods of between 50 and 1000 is may be advantageous. A modulation of this kind corresponds to quasi static broadening of the line width of the laser radiation to the value of the modulation amplitude, i.e. up to 500 MHz. In this case, the requirement for the filter bandwidth is no longer specified by the natural line width of the laser light source, but instead by the line width broadened in accordance with the chirping amplitude (10-500 MHz).

The notch filter performs filtering only in the spectral range specified by the filter notch, while no filter effect occurs either in the case of higher or in the case of lower frequencies. Automatic stabilization of the filter can thus be achieved, since an error signal can be generated by means of modulation of the filter or laser.

An optical amplifier suitable for the laser system, specifically a Raman fiber amplifier, is disclosed for example in EP 2 081 264 A1. In addition, reference is made to the publication by Luke R. Taylor et al. (“50 W CW visible laser source at 589 nm obtained via frequency doubling of three coherently combined narrow-band Raman fiber amplifiers”, Optics Express, Vol. 18, No. 8, 8540). Other types of amplifier are also possible, however.

In view of the applications addressed at the outset, in the laser system, in the spectrum of the laser radiation filtered by means of the notch filter the frequency of the carrier corresponds to a fluorescence frequency, and the frequency of the remaining sideband corresponds to a back-pumping frequency, wherein the fluorescence frequency is resonant with the transition frequency of an (approximately cyclical) optical transition, e.g. in an atom, i.e. a line in the electronic excitation spectrum of the atom, in an atom assembly or in an atom-like solid-state system (e.g. quantum point) as a component of a quantum information system, and the frequency spacing between the back-pumping frequency and the fluorescence frequency corresponds to the hyperfine splitting of the optical transition. In order to generate an artificial guide star by means of fluorescence excitation of the sodium atoms in the mesosphere, the fluorescence frequency of the laser radiation should correspond to a wavelength of 589 nm, while the frequency spacing of the back-pumping frequency from the carrier frequency is for example 1.7 GHz. This frequency spacing corresponds to the hyperfine splitting of the relevant sodium line.

In a further preferred embodiment, the laser light source of the laser system is a diode laser comprising at least one laser diode, wherein the modulation means performs high-frequency modulation of the injection current of the laser diode during operation of the laser system. Modulation of the injection current by means of a high frequency is a widespread method for generating spectral sidebands, which method is widely used in the field of telecommunications and also in the field of quantum optics. This type of “electronic” modulation is particularly easy to implement. As a result, the laser system can be provided at a significantly lower cost than laser systems that operate using alternative modulators, such as electro-optic modulators.

In a possible embodiment, serrodyne modulation may be used, alternatively or in addition to the optical filter, in order to generate single-sideband modulated laser radiation. In this case, the laser radiation emitted by the laser light source during operation is modulated by means of a sawtooth and/or stepped modulation signal, in particular when the modulation is performed by means of high-frequency modulation of the injection current of the laser diode. In this way, it is possible to purposely generate sidebands having different intensities, instead of the conventional two symmetrical sidebands. This makes it possible to generate the sideband that is involved subsequently in the frequency multiplication or sum-frequency generation for generating the radiation at the back-pumping frequency, so as to be of as high an intensity as possible. For this purpose, at least in the case of modulation frequencies of up to 2 GHz, it is possible to use an electro-optic modulator. In this case, the sawtooth modulation waveform can be generated for example by means of a comb generator, for example a sine wave generator, in combination with a suitable non-linear transmission line (NLTL). It may be possible, however, that generation of (approximately) purely single-sideband modulated laser radiation can be achieved only with difficultly using this method. In particular, the characteristics of the non-linear transmission line can be mastered only with difficulty. It may therefore be possible that the generated laser radiation may not only comprise the desired spectral components of the carrier and of the single sideband, wherein further (interfering) components, in particular the sideband that is actually to be suppressed, are not suppressed adequately.

In a preferred embodiment of the laser system, the optical notch filter is a fiber-Bragg grating, in particular a π-phase-shifted fiber-Bragg grating (πFBG), which, during operation of the laser system, transmits the spectral portion of the laser radiation at the frequency of one sideband, and reflects the spectral portions at the frequency of the carrier and the frequency of the other sideband. A πFBG is a type of fiber-Bragg grating, the reflection spectrum of which comprises a notch. This property results from a π-phase discontinuity in the center of the grating. Introducing the π-phase discontinuity into the refractive index modulation of the fiber-Bragg grating during the production thereof means that the spectral transmission exhibits a narrow band-pass resonance that results in the center of the reflection spectrum of the fiber-Bragg grating. This notch in the reflection spectrum is suitable, in accordance with the specifications explained above with respect to the filter bandwidth and edge steepness, for generating single-sideband modulated laser radiation. Owing to the phase discontinuity, a πFBG can be referred to, conceptually, as a Fabry-Perot cavity, which consists of two fiber-Bragg reflectors. If the two fiber-Bragg gratings are highly reflective, high quality of the Fabry-Perot cavity results, which in turn leads to an extremely narrow spectral notch in the reflection spectrum. In this embodiment, the notch filter in the form of the πFBG transmits the undesired sideband that coincides, spectrally, with the notch in the reflection spectrum of the πFBG, while the carrier and the desired sideband are located outside of the notch filter and are accordingly reflected. The undesired sideband is removed from the laser radiation in this manner.

In a further preferred embodiment, the light-conducting fiber of the πFBG is thermally coupled to a temperature-control means, preferably a cooler, particularly preferably a thermoelectric cooler. The temperature-control means is used to keep the πFBG at a particular temperature in order to thereby control the filter, or more precisely the spectral position of the notch, and to calibrate it to the sideband that is to be removed. The detuning of the filter by means of temperature control is based on the thermal expansion of the light-conducting fiber. The thermal expansion changes the spacings of the refractive index modulations along the fiber, and thus the spectral position of the filter characteristics. In this case, the cooler should have a sufficient thermally active mass (i.e. heat capacity) in order to bring about (passive) stabilization of the filter. It is also conceivable to mechanically deform the light-conducting fiber (by means of stretching/compression) in order to control the spectral position of the notch, and to calibrate it to the sideband that is to be removed.

In a further embodiment, the light-conducting fiber of the πFBG is additionally thermally coupled to a further temperature-control means, e.g. an electrical heating element, in particular a heating wire, the heat capacity of which is comparatively small. The further temperature-control means makes it possible to bring about a corresponding modulation of the spectral position of the notch by the frequency value set by the first temperature-control means, by means of modulating the temperature. As a result, it is possible to generate an error signal for active stabilization of the filter, in accordance with a lock-in method (“top-of-fringe” or also “side-of-fringe”). A control loop comprising a sensor that derives a control variable from the laser radiation filtered by means of the notch filter, and a controller that stabilizes the notch filter at the frequency of the sideband to be removed, is expediently used for this purpose. In this case, the controller actuates the two temperature-control means. A simple photo detector is advantageously possible as the sensor, which photo detector detects the intensity of the sideband transmitted by the πFBG as the control variable.

In a further embodiment, the laser system comprises a stabilization means that is assigned to the laser light source and that regulates the frequency of the carrier to a specifiable value. A conventional stabilization means can be used for this purpose, which stabilization means couples the frequency of the carrier of the laser radiation to an absolute reference, e.g. by means of absorption spectroscopy or another suitable frequency measuring device, wherein, for example in the case of a semiconductor laser as the laser light source, the diode current functions as the manipulated variable.

The method of the invention advantageously comprises a start-up procedure, in which at least the following method steps are performed:
activating the laser light source;
activating the modulation of the laser radiation;
detecting the characteristics of the optical notch filter;
setting and stabilizing the notch filter at the frequency of the sideband to be removed.

Firstly, the laser light source is activated and set and stabilized at the desired carrier frequency. The modulation of the laser radiation, using the desired modulation frequency, is then activated, in order to generate the sidebands that are arranged symmetrical with respect to the carrier and at the desired spectral spacing from the carrier. In order for it to be possible for the notch filter to be suitably adjusted to the sideband that is to be removed, the characteristics of the notch filter are first detected by means of detuning the notch filter. Since the frequency of the filter notch is systematically detuned relative to the (fixed) spectrum of the laser radiation, it is possible, for example by means of detecting the radiation transmitted by the πFBG, for the exact spectral position of the filter notch to be determined, in order that said notch can then be purposely matched to the frequency of the undesired sideband. The stabilization of the notch filter at the frequency of the sideband to be removed is then activated. Finally, the optical amplifier can be activated, for the purpose of final amplification of the single-sideband modulated laser radiation obtained.

More preferably, the method according to the invention comprises the following further method steps:
monitoring the power of the laser radiation fed to the optical amplifier;
shutting down the optical amplifier as soon as the power of the laser radiation fed to the optical amplifier falls below a specifiable threshold value.

During operation, it is necessary to ensure that the laser radiation reaches the optical amplifier at a certain power, because otherwise the amplifier, which is configured for high powers, may be damaged or destroyed. If the notch filter, for example in the form of the transmitting πFBG, is incorrectly activated, for example in the event of failure of the stabilization, it is possible that the carrier may come to match the filter notch, with the result that only the low power of the sidebands continues to reach into the amplifier. In this case, emergency shutdown of the optical amplifier takes place automatically, in order to prevent damage. The emergency shutdown can for example be activated as soon as the detected power (inherently intended for stabilizing the filter) of the laser radiation transmitted by the πFBG exceeds a threshold value.

In practical applications, it may be necessary to detune the carrier frequency of the laser radiation, such that for example the laser radiation is purposely brought out of resonance with an atomic optical transition. This is expediently achieved in that the frequency of the carrier is detuned from a first value to a second value, and specifically by a frequency spacing that is greater than the frequency spacing between the sideband and the carrier, wherein the frequency direction of the detuning is selected such that the spectral portion of the laser radiation at the frequency of the carrier is not removed by the notch filter during the detuning process. This reliably ensures that sufficient power always reaches into the optical amplifier.

The laser system may be designed integrally with an arithmetic unit, and/or be actuatable by means of an arithmetic unit. The arithmetic unit may be configured to actuate the notch filter, for example by means of special software, such that said filter removes the undesired sideband, as described above. Said unit may furthermore be configured to perform at least some of the steps or all of the steps of the method described above, and to actuate the involved hardware components accordingly.

### BRIEF DESCRIPTION OF THE DRAWINGS

Embodiments of the laser system and the method will be explained in greater detail in the following, with reference to the drawings, in which:

FIG. 1: is a block diagram of the laser system;

FIG. 2: illustrates the spectral filter pattern;

FIG. 3: schematically shows the notch filter comprising temperature control;

FIG. 4: is a flow diagram illustrating the start-up process of the laser system, comprising sideband modulation;

FIG. 5: is a flow diagram illustrating the start-up process of the laser system, without sideband modulation;

FIG. 6: is a flow diagram illustrating the detuning process of the laser system;

FIG. 7: illustrates the stabilization of the notch filter and the detuning process;

FIG. 8: is a block diagram illustrating an alternative embodiment of the laser system, comprising serrodyne modulation.

### DETAILED DESCRIPTION OF EMBODIMENTS

The laser system shown in FIG. 1 comprises a laser light source 1 which is a diode laser. The laser light source 1 is connected to a modulation means 2 that performs high-frequency modulation of the injection current of the laser diode (not shown) of the laser light source 1. The modulation frequency is 1.7 GHz. As a result of this modulation frequency, the spectrum of the radiation emitted by the laser light source 1 obtains a sideband that is the basis for the generation of radiation at the back-pumping frequency in accordance with the hyperfine structure of the sodium D-line. The spectrum of the radiation emitted by the laser light source 1 comprises a component at a carrier frequency of 1178 nm. The frequency spacing from the carrier frequency to the two sidebands is +−1.7 GHz, depending on the modulation frequency. The spectrum comprising the carrier and the two sidebands arranged symmetrically thereto at the output of the laser light source 1 is indicated schematically in FIG. 1.

The modulated laser radiation is supplied to a first port of a circulator 3 by means of an optical fiber. The laser radiation then reaches an optical notch filter 4 via a second port. The frequency of the filter notch of the optical notch filter 4 is matched to the frequency of a sideband of the laser radiation. Accordingly, the notch filter 4 transmits only the sideband of the laser radiation, as indicated schematically at the output of the notch filter 4. The carrier and the other sideband are reflected by the notch filter 4, return to the second port of the circulator 3, and leave said circulator via the third port thereof.

From the third port of the circulator 3, the now single-sideband modulated laser radiation of the laser light source 1 is supplied to a Raman fiber amplifier 5. The amplifier fiber (not shown) of the fiber amplifier 5 is optically pumped by means of a pump laser (not shown). The Raman fiber amplifier 5 amplifies the laser radiation at the carrier frequency and at the frequency of the remaining sideband. The amplification bandwidth of the Raman fiber amplifier 5 is correspondingly large. At the output of the Raman fiber amplifier 5, the power of the laser radiation is approximately 30 to 40 W in total, and even more than 100 W can be achieved in practice.

The laser radiation thus amplified is supplied to a resonant frequency multiplier 6. In this case, this is a nonlinear crystal that is located inside an optical resonator. The frequency multiplier 6 converts the amplified radiation by means of frequency multiplication and sum-frequency generation. The spectrum of the radiation at the output of the frequency multiplier 6 comprises intensities at a fluorescence frequency and at a back-pumping frequency, wherein the fluorescence frequency corresponds to the sodium D-line, and the frequency spacing of the back-pumping frequency from the fluorescence frequency corresponds to the hyperfine splitting of the corresponding sodium D-line. In this case, the power of the radiation at the output of the frequency multiplier 6 can be significantly above 20 W, which is advantageous for example for generating an artificial guide star for astronomical telescopes comprising adaptive optics.

The spectrum of the amplified laser radiation results after the frequency multiplication or sum-frequency generation using the frequency multiplier 6. The carrier is generated at the fluorescence frequency of 589 nm. This central spectral line results from frequency doubling of the original carrier frequency. Furthermore, the amplified spectrum exhibits a sideband that is spaced apart from the fluorescence frequency by 1.7 GHz. This sideband results from the carrier and the sideband of the original spectrum by means of sum-frequency generation. Furthermore, after passing through the frequency multiplier 6 a further sideband is present that results from frequency doubling of the sideband from the original spectrum. However, said sideband is significantly attenuated and is therefore of no further relevance. The sideband obtained by sum-frequency generation, at 1.7 GHz, is provided at the back-pumping frequency. For high fluorescence, the intensity at the back-pumping frequency should be at least 10% of the intensity at the fluorescence frequency. In order to achieve this, sum-frequency generation is used. In this case, use is made of the fact that the resulting intensity in the case of sum-frequency generation behaves like the products of the intensities of the fundamental light fields.

In order to stabilize the notch filter 4, such that the notch frequency is matched to the undesired sideband of the laser radiation, a control loop is provided, comprising a photo diode 7 as the sensor, which photo diode detects the intensity of the sideband transmitted by the notch filter 4, as a control variable. The control loop further comprises a controller 8 that stabilizes the notch filter 4 at the frequency of the sideband to be removed. This is achieved for example in accordance with a lock-in scheme, for which purpose the controller 8 modulates the notch frequency and thus imposes an error signal on the control variable, which signal the controller 8 in turn derives, in narrow-band, from the signal of the photo diode 7. A regulating bandwidth of from a few Hz to a few 10 Hz is sufficient, in practice, for stabilizing the notch filter 4.

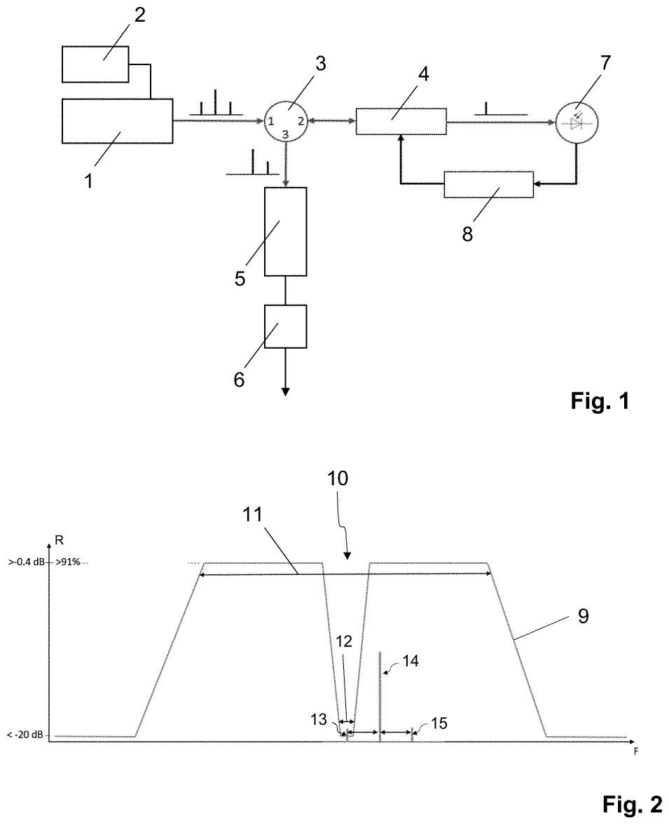

Advantageously, a π-phase-shifted fiber-Bragg grating is used as the notch filter, which grating transmits the spectral portion of the laser radiation at the frequency of one sideband, and reflects the spectral portions at the frequency of the carrier and the frequency of the other sideband. The filter characteristics of a suitable πFBG are shown in FIG. 2. The graph in FIG. 2 shows the reflectivity R as a function of the frequency F. It can be seen that the reflection spectrum 9 comprises a notch 10. This property results from the π-phase discontinuity in the center of the fiber-Bragg grating. The spectral overall width 11 of the reflection spectrum 9 is in the range of over 10 GHz. The spectral width 12 of the notch 10 is less than 1 GHz (full width at half the height of the reflection curve 9). As can be seen, the optical notch filter formed by the πFBG is sufficiently narrow-band and has a high degree of edge steepness, in order to separate the sideband 13, likewise shown in FIG. 2, from the carrier 14. Furthermore, the filter bandwidth is sufficiently large, specifically larger than the laser bandwidth (typically <10 MHz), in order that the undesired sideband 13 can be completely removed. At the same time, the filter bandwidth is sufficiently narrow compared with the spacing between the carrier and sideband, i.e. narrower than the modulation frequency (in this case 1.7 GHz). It can be seen that the filter notch 10 coincides with the sideband 13. The sideband 13 is thus transmitted by the filter 4 formed by the πFBG. The carrier 14 and the desired sideband 15 are in the range of high reflectivity of the πFBG (maximum reflectivity ca. 91%). These spectral components of the laser radiation are thus reflected. In this way, the sideband 13 is removed from the laser radiation by means of the transmitting notch filter 4, in order to thus maintain single-sideband modulated laser radiation.

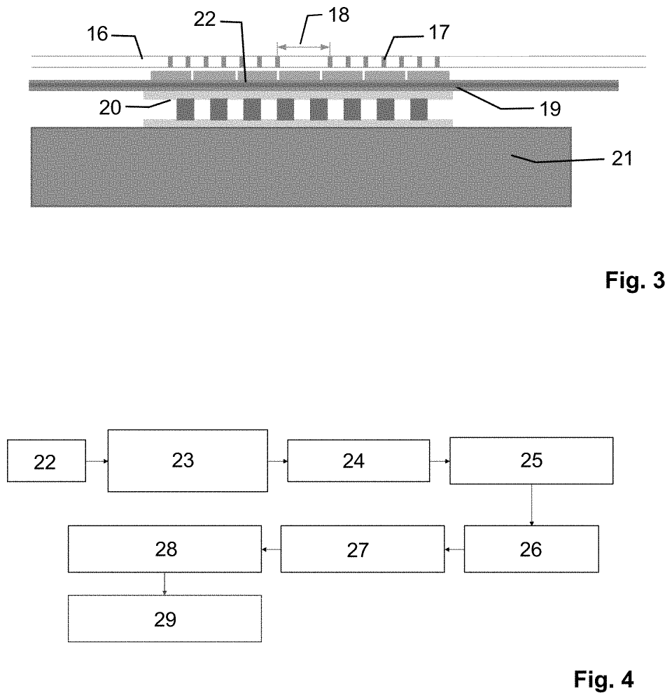

FIG. 3 shows a light-guiding fiber 16 having inscribed refractive index modulation 17, which fiber forms the πFBG. Introducing the π-phase discontinuity 18 into the refractive index modulation 17 of the fiber-Bragg grating is achieved in that the spectral transmission exhibits a narrow band-pass resonance 10 which, as shown in FIG. 2, results in the center of the reflection spectrum 9. The spectral position of the filter notch 10 can be controlled by means of the thermal expansion of the light-conducting fiber 16. For this purpose, in FIG. 3 the light-conducting fiber 16 is attached to a printed circuit board (PCB) 19 which is in turn in thermal contact with a thermoelectric cooler (Peltier element) 20. Said cooler dissipates the heat to a heat sink 21 having a sufficiently large heat capacity. The fiber 16 is furthermore in thermal contact with an electrical heating element 22. Actuating the cooler 20 makes it possible to set a specified temperature of the light-conducting fiber 16 in thermal equilibrium, such that the filter notch 10 is at the desired frequency. The frequency position of the filter notch 10, and thus the intensity of the transmitted radiation of the sideband 13, is modulated accordingly by means of modulating a heater current flowing through the heating element 22. In this case, the modulation amplitude should be less than the spectral width 12 of the transmission. In this way, an error signal arises at the detector 7 (FIG. 1), which signal, as described above, can be used for active stabilization of the notch filter 4.

The method for actuating the notch filter 4 is non-trivial in practice, in order to provide an uninterrupted input signal for the optical amplifier 5, even in the case of different sideband modulation amplitudes, including complete shutdown of the modulation, as well as detuning of the carrier frequency, optionally by many times the sideband frequency. That is to say that it is necessary to ensure that the carrier frequency of the laser radiation never coincides with the frequency of the filter notch 10, i.e. the transmission frequency of the filter 4. Otherwise, there is a risk of damage to/destruction of the optical amplifier 5.

In this respect, FIG. 4 is a flow diagram illustrating the start-up process of the laser system, comprising sideband modulation. The procedure begins, in step 22, with starting up the semiconductor laser 1 by means of activating the injection current. In step 23, the stabilization of the laser emission is activated, e.g. in the conventional manner firstly by setting the temperature of the laser diode and of the injection current to a target value (known in advance), such that the semiconductor laser emits approximately at the desired frequency, and then by means of active stabilization at a suitable absolute reference (e.g. using a wavelength measuring device or by means of absorption spectroscopy). A rapid control loop, e.g. comprising the injection current as the manipulated variable, is used for this purpose. Thereafter, in step 24 the sideband modulation is activated, by means of direct modulation of the injection current of the laser diode or by means of modulation of the emitted laser radiation using an electro-optic modulator. In the next step, i.e. in step 25, detection of the filter characteristics of the notch filter 4 is performed, in order to thereby determine the spectral position of the filter notch 10. In this case, the notch filter 4 is detuned over a predefined spectral range (by actuating the cooler 20; see FIG. 3). At the same time, the course of the transmitted power is detected by means of the photo diode 7 (FIG. 1) and recorded. In step 26, an automatic analysis (e.g. peak detection) takes place on the basis of the recorded signals of the photo diode 7, as a result of which the spectral position of the undesired sideband 13, and thus the target value of the filter setting and the associated value of the manipulated variable of the notch filter 4, are determined. A storage oscilloscope or a suitably programmed embedded system, e.g. as a component of the controller 8, can be used for this purpose. In step 27, the corresponding initialization of the notch filter 4 then takes place, i.e. the notch filter 4 is set to the previously determined target value of the transmission frequency, e.g. by means of corresponding actuation of the cooler 20 (FIG. 3). A suitable (slow) control loop may be provided for stabilizing the temperature of the πFBG that determines the transmission frequency. Finally, in step 28, the active stabilization of the notch filter 4 is activated, for which purpose, as described above, an error signal is generated by the heating element 22, and the manipulated variable is derived therefrom, by means of the controller 8, for setting the temperature of the πFBG. In parallel thereto, in step 29 the continuous monitoring of the power of the power transmitted by the notch filter 4 is activated. An emergency shutdown of the optical amplifier 5 (e.g. by means of shutting down the pump radiation) is initiated as soon as a threshold value of the power on the photo diode 7 is exceeded. This is considered to be a sign that the carrier is transmitted from the notch filter 4, and accordingly too little power is reaching into the amplifier 5. The threshold value may be firmly specified, or may be dependent on the modulation amplitude.

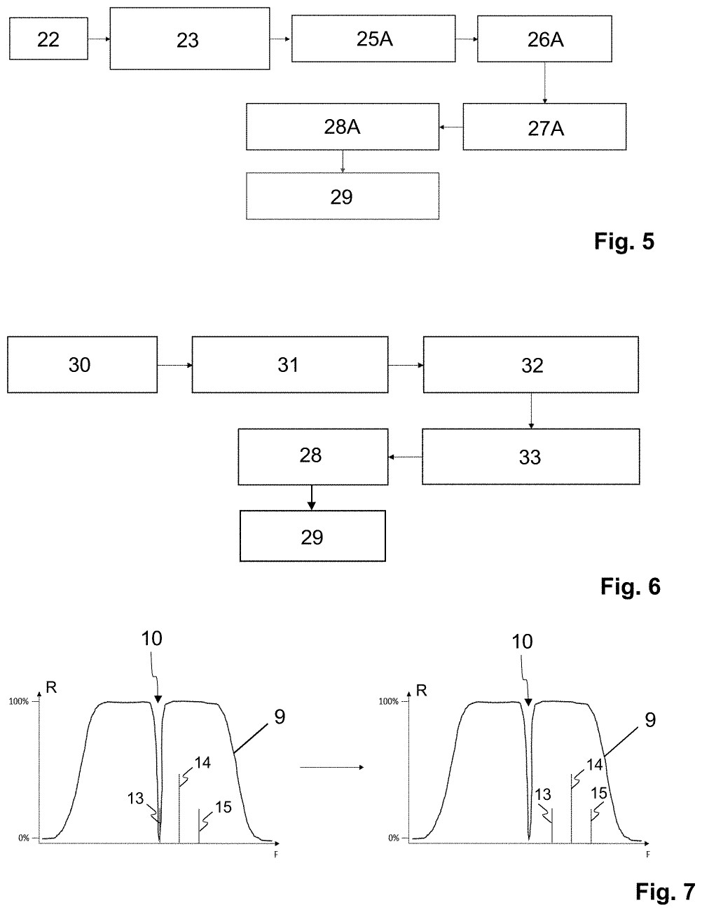

The laser system should also be able to function without sideband modulation. A start-up procedure suitable for this purpose is illustrated in FIG. 5. The activation and stabilization of the laser light source again takes place, in steps 23 and 24. The activation of the modulation is omitted. In steps 25A and 26A, the notch filter 4 is tuned and the transmission system detected in the process is analyzed, wherein, in step 27A, the notch filter 4 is then initialized such that the filter notch 10 is located close to the (only available) carrier. In this case, the notch filter 4 is detuned until a low transmission signal is detected. The stabilization of the notch filter 4 is then activated in step 28A, using the low transmission signal as the target value of the control variable. As a result, the notch filter 4 is stabilized such that the filter notch 10 is located spectrally close beside the carrier, but the major part of the carrier is reflected. Alternatively, the notch filter 4 may be detuned by a specified frequency offset relative to the frequency of the carrier, such that it is reliably ensured, without actively stabilizing the notch filter 4, that a sufficient spacing exists between the carrier and the filter notch 10, and also that drifting cannot lead to the carrier being transmitted. In parallel thereto, the monitoring and emergency shutdown is activated in step 29, as described above with reference to FIG. 4.

In particular when generating an artificial guide star, it is necessary to regularly shift the carrier frequency from a first, resonant value to a second, non-resonant value, at which no resonance fluorescence occurs in the sodium layer. The detuning must take place at (significantly) more than the line width of the laser, and also more than the modulation frequency. In the detuned state, the Rayleigh scattering background which the laser generates on its path through the lower levels of the earth's atmosphere can be detected separately, in order to be used for correcting the astronomical image data. A procedure suitable for this purpose is shown in FIG. 6. In step 30, the active (lock-in) stabilization of the notch filter 4 is interrupted, and only the passive stabilization, at the previously determined target frequency of the filter notch 10, is maintained. Then, in step 31, the active stabilization of the laser light source 1 is deactivated and the frequency of the carrier is detuned from the value last set to the desired second value (e.g. by means of setting a previously specified diode temperature), wherein the frequency direction of the detuning is selected such that the spectral portion of the laser radiation at the frequency of the carrier does not pass through the notch filter 10 during the detuning process. In other words, the shift of the carrier 14 takes place in the direction away from the filter notch 10. Upon reaching the new target value of the carrier frequency, the stabilization of the laser light source 1 at the new carrier frequency is again activated. In step 32, the measurement of the background signal is then performed at the telescope. In step 33, back-detuning of the laser radiation to the resonant carrier frequency takes place. This step is critical because it is necessary to prevent, in this case, the carrier coming into superimposition with the filter notch 10. Even at a slight overshoot of the control variable (e.g. the diode temperature), the carrier would enter the region of the filter notch 10, as a result of which the input signal would break at the optical amplifier 5. Regulation that is carefully matched to the specific interaction between the notch filter 4 and the carrier frequency is necessary here. It is thus possible, for example, to compensate for overshoots of the slower temperature regulation of the laser diode by means of corresponding counter control using the injection current of the laser diode. Finally, in step 28, the stabilization of the notch filter 4 is activated again. The monitoring and emergency shutoff 29, as described above, takes place in parallel therewith.

FIG. 7 illustrates the above-described detuning process. In the left-hand graph of FIG. 7, the notch filter 4 is stabilized such that the sideband 13 to be removed corresponds exactly to the filter notch 10. The right-hand graph shows that the frequencies of the assembly of the three lines 13, 14, 15 (sidebands and carrier) are shifted together to the right, i.e. the frequency direction of the detuning is selected such that the spectral portion of the laser radiation at the frequency of the carrier 14 does not pass through the filter notch 10 during the detuning process. The filter characteristics of the notch filter 4 remain sufficiently stable during the detuning process, as a result of the passive stabilization.

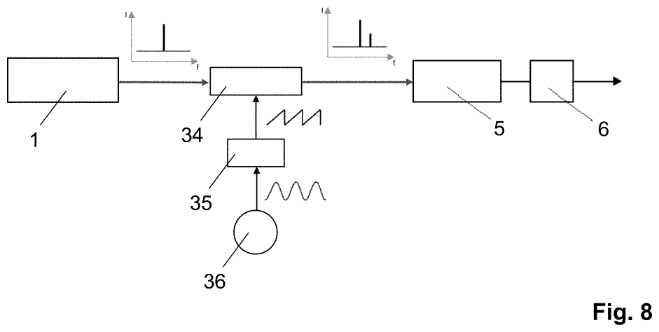

In FIG. 8 and FIG. 1, mutually corresponding elements of the laser systems shown schematically in each case are denoted by the same reference signs. In the embodiment of FIG. 8, differently from FIG. 1 a serrodyne modulation is used. In this case, the laser radiation emitted by the laser light source 1 during operation is modulated by means of an electro-optic modulator 34. A sawtooth modulation signal is applied to said radiation. In this way, it is possible to purposely generate sidebands having different intensities, instead of the conventional two symmetrical sidebands. This makes it possible to generate the sideband that is involved subsequently, i.e. following the amplification, in the frequency multiplication or sum-frequency generation for generating the radiation at the back-pumping frequency, so as to be of a significantly higher intensity than the other, undesired sideband. At the output of the electro-optic modulator 34, FIG. 8 shows, in simplified form, the spectrum of the laser radiation having only the desired sideband. In this case, the sawtooth modulation waveform is generated by means of a sine wave generator (VCO) 35, in combination with a non-linear transmission line 36.

1. Laser system, comprising
a laser light source that is configured to emit laser radiation during operation of the laser system,
a modulation means that is configured for modulating the emitted laser radiation such that the frequency spectrum of the laser radiation comprises a carrier and two sidebands that are symmetrically distributed around the carrier, and
at least one optical amplifier that is configured for amplifying the laser radiation,
wherein an optical filter is arranged in the beam path of the laser radiation, upstream of the optical amplifier, which filter is configured to remove the spectral portion of the laser radiation at the frequency of one of the two sidebands.

2. Laser system according to claim 1, wherein the optical filter is an optical notch filter.

3. Laser system according to claim 1, wherein the optical filter is a fiber-Bragg grating, in particular a π-phase-shifted fiber-Bragg grating, which grating transmits the spectral portion of the laser radiation at the frequency of one sideband, and reflects the spectral portions at the frequency of the carrier and the frequency of the other sideband.

4. Laser system according to claim 3, wherein a light-guiding fiber of the fiber-Bragg grating is thermally coupled to a temperature-control means, preferably a cooler, particularly preferably a thermoelectric cooler.

5. Laser system according to claim 3, wherein the light-guiding fiber of the fiber-Bragg grating is thermally coupled to a temperature-control means, preferably an electrical heating element, in particular a heating wire.

6. Laser system according to claim 1, further comprising a control loop comprising a sensor that is configured to derive a control variable from the laser radiation filtered by means of the optical filter, and a controller that is configured to stabilize the filter to the frequency of the sideband to be removed.

7. Laser system according to claim 4, wherein the controller is connected to the two temperature-control means.

8. Laser system according to claim 7, wherein the controller is configured to modulate the temperature of the fiber-Bragg grating, by means of actuating the further temperature-control means, so as to generate an error signal.

9. Laser system, comprising
a laser light source that is configured to emit laser radiation during operation of the laser system,
a modulation means that is configured for serrodyne modulation of the emitted laser radiation such that the frequency spectrum of the laser radiation comprises a carrier and at least one sideband,
at least one optical amplifier that is configured for amplifying the laser radiation.

10. Laser system according to claim 9, wherein the modulation means comprises a sine wave generator and a non-linear transmission line connected downstream thereof, which are configured for generating a sawtooth modulation signal.

11. Laser system according to claim 1, further comprising a stabilization means that is assigned to the laser light source and that is configured to regulate the frequency of the carrier to a specifiable value.

12. Laser system according to claim 1, wherein, in the spectrum of the amplified laser radiation, the frequency of the carrier corresponds to a fluorescence frequency, and the frequency of the sideband corresponds to a back-pumping frequency, wherein
the fluorescence frequency is resonant with a transition frequency of an optical transition, and
the frequency spacing of the back-pumping frequency from the fluorescence frequency is resonant with the hyperfine splitting of the optical transition.

13. Laser system according to claim 12, wherein the fluorescence frequency of the transition frequency corresponds to the sodium line, at a wavelength of 589 nm, and the frequency spacing of the back-pumping frequency from the fluorescence frequency is 1.7 GHz.

14. Laser system according to claim 1, wherein the laser light source is a
diode laser comprising at least one laser diode, wherein the modulation means is configured for modulating the injection current of the laser diode.

15. Use of a laser system according to claim 1 for generating an artificial guide star (“laser guide star”) for astronomical telescopes comprising adaptive optics.

16. Use of a laser system according to claim 1 for exciting optical transitions in a quantum information system.

17. Method for generating laser radiation, comprising the method steps of
generating laser radiation by means of a laser light source;
modulating the laser radiation such that the spectrum of the laser radiation comprises a carrier (14) and two sidebands that are symmetrically distributed around the carrier, and
amplifying the laser radiation,
wherein the modulated laser radiation passes through an optical filter prior to amplification, which filter removes the spectral portion of the laser radiation at the frequency of one of the two sidebands.

18. Method according to claim 17, wherein a start-up procedure comprising at least the following method steps is performed:
activating the laser light source;
activating the modulation of the laser radiation;
detecting the characteristics of the optical notch filter;
setting and stabilizing the notch filter to the frequency of the sideband to be removed.

19. Method according to claim 17, comprising the following further method steps:
monitoring the power of the laser radiation fed to the optical amplifier;
shutting down the optical amplifier as soon as the power of the laser radiation fed to the optical amplifier falls below a specifiable threshold value.

20. Method according to claim 17, wherein the frequency of the carrier is detuned from a first value to a second value, and specifically by a frequency spacing that is greater than the frequency spacing between the sideband and the carrier, wherein the frequency direction of the detuning is selected such that the spectral portion of the laser radiation at the frequency of the carrier is not removed by the notch filter during the detuning process.

21. Method for generating laser radiation, comprising the method steps of
generating laser radiation by means of a laser light source;
serrodyne modulation of the laser radiation such that the spectrum of the laser radiation comprises a carrier and two sidebands of different intensities that are symmetrically distributed around the carrier, and
amplifying the laser radiation.
